(19) United States
(12) Patent Application Publication
(10) Pub. No.: US 2022/0128697 A1
(43) Pub. Date: Apr. 28, 2022

(54) IMAGE SENSORS FOR LIDAR SYSTEMS

(71) Applicant: Shenzhen Genorivision Technology Co. Ltd., Shenzhen (CN)

(72) Inventors: Peiyan CAO, Shenzhen (CN); Yurun LIU, Shenzhen (CN)

(21) Appl. No.: 17/571,942

(22) Filed: Jan. 10, 2022

Related U.S. Application Data
(63) Continuation of application No. PCT/CN2019/098265, filed on Jul. 30, 2019.

(51) Int. Cl. G01S 17/894; G01S 7/481; G01S 7/4865; G01B 11/24

(52) U.S. Cl. CPC G01S 17/894; G01B 11/24; G01S 7/4865; G01S 7/4816

(57) ABSTRACT

Disclosed herein is a method of operating an apparatus which comprises (a) an image sensor comprising an array of avalanche photodiodes (APDs)(i), i=1, . . . ,N, N being a positive integer, (b) a radiation source, and (c) an optical system, the method comprising: using the radiation source to emit a pulse of illumination photons at a time point Ta; for i=1, . . . ,N, measuring a time of flight (i) from Ta to a time point Tb(i) at which a photon of the illumination photons returns to the APD (i) through the optical system after bouncing off a surface spot (i) of a targeted object corresponding to the APD (i); and determining a three-dimensional contour of the targeted objects based on the times of flights (i), i=1, . . . ,N. The optical system comprises a first cylindrical lens and a second cylindrical lens. The first cylindrical lens is positioned between the targeted objects and the second cylindrical lens.

### TECHNICAL FIELD

The disclosure herein relates to image sensors for Lidar (Light Detection and Ranging) systems.

### BACKGROUND

An image sensor or imaging sensor is a sensor that can detect a spatial intensity distribution of a radiation. An image sensor usually represents the detected image by electrical signals. Image sensors based on semiconductor devices may be classified into several types, including semiconductor charge-coupled devices (CCD), complementary metal-oxide-semiconductor (CMOS), and N-type metal-oxide-semiconductor (NMOS).

In addition to being used for capturing a two-dimensional (2D) image of objects (i.e., for detecting a spatial intensity distribution of an incoming radiation) as mentioned above, an image sensor can also be used in a Lidar (Light Detection and Ranging) system for capturing a range image of objects (i.e., for detecting a spatial distance distribution of incoming radiation).

### SUMMARY

Disclosed herein is a method of operating an apparatus which comprises (a) an image sensor comprising an array of avalanche photodiodes (APDs)(i), i=1, . . . ,N, N being a positive integer, for i=1, . . . ,N, the APD (i) comprising an absorption region (i) and an amplification region (i), wherein the absorption region (i) is configured to generate charge carriers from a photon absorbed by the absorption region (i), wherein the amplification region (i) comprises a junction (i) with a junction electric field (i) in the junction (i), wherein the junction electric field (i) is at a value sufficient to cause an avalanche of charge carriers entering the amplification region (i), but not sufficient to make the avalanche self-sustaining, and wherein the junctions (i), i=1, . . . ,N are discrete, (b) a radiation source, and (c) an optical system, the method comprising: using the radiation source to emit a pulse of illumination photons at a time point Ta; for i=1, . . . ,N, measuring a time of flight (i) from Ta to a time point Tb(i) at which a photon of the illumination photons returns to the APD (i) through the optical system after bouncing off a surface spot (i) of a targeted object corresponding to the APD (i); and determining a three-dimensional (3D) contour of the targeted objects based on the times of flights (i), i=1, . . . ,N.

According to an embodiment, N is greater than 1.

According to an embodiment, the illumination photons comprise infrared photons, and for i=1, . . . ,N, the APD (i) comprises silicon.

According to an embodiment, for i=1, . . . , N, the absorption region (i) has a thickness of 10 microns or above.

According to an embodiment, for i=1, . . . ,N, an absorption region electric field (i) in the absorption region (i) is not high enough to cause avalanche effect in the absorption region (i).

According to an embodiment, for i=1, . . . ,N, the absorption region (i) is an intrinsic semiconductor or a semiconductor with a doping level less than 10¹² dopants/cm³.

According to an embodiment, N>1, and at least some absorption regions of the absorption regions (i), i=1, . . . ,N are joined together.

According to an embodiment, for i=1, . . . ,N, the APD (i) further comprises an amplification region (i′) such that the amplification region (i) and the amplification region (i′) are on opposite sides of the absorption region (i).

According to an embodiment, the amplification regions (i), i=1, . . . ,N are discrete.

According to an embodiment, for i=1, . . . ,N, the junction (i) is a p-n junction or a heterojunction.

According to an embodiment, for i=1, . . . ,N, the junction (i) comprises a first layer (i) and a second layer (i), and for i=1, . . . ,N, the first layer (i) is a doped semiconductor and the second layer (i) is a heavily doped semiconductor.

According to an embodiment, for i=1, . . . ,N, the junction (i) further comprises a third layer (i) sandwiched between the first layer (i) and the second layer (i), and for i=1, . . . ,N, the third layer (i) comprises an intrinsic semiconductor.

According to an embodiment, N>1, and at least some third layers of the third layers (i), i=1, . . . ,N, are joined together.

According to an embodiment, for i=1, . . . ,N, the first layer (i) has a doping level of 10¹³ to 10¹⁷ dopants/cm³.

Docket No. 1810-0132

According to an embodiment, N>1, and at least some first layers of the first layers (i), i=1, . . . ,N are joined together.

According to an embodiment, the image sensor further comprises electrodes (i), i=1, . . . ,N in electrical contact with the second layers (i), i=1, . . . ,N, respectively.

According to an embodiment, the image sensor further comprises a passivation material configured to passivate a surface of the absorption regions (i), i=1, . . . ,N.

According to an embodiment, the image sensor further comprises a common electrode electrically connected to the absorption regions (i), i=1, . . . ,N.

According to an embodiment, for i=1, . . . ,N, the junction (i) is separated from a junction of a neighbor junction by (a) a material of the absorption region (i), (b) a material of the first layer (i) or of the second layer (i), (c) an insulator material, or (d) a guard ring (i) of a doped semiconductor.

According to an embodiment, for i=1, . . . ,N, the guard ring (i) is a doped semiconductor of a same doping type as the second layer (i), and for i=1, . . . ,N, the guard ring (i) is not heavily doped.

According to an embodiment, the method further comprises matching the determined 3D contour against a previously known 3D contour.

According to an embodiment, the optical system is configured to converge photons incident on the optical system.

According to an embodiment, the optical system comprises a first cylindrical lens and a second cylindrical lens, and the first cylindrical lens is positioned between the targeted objects and the second cylindrical lens.

According to an embodiment, the first cylindrical lens is configured to converge photons incident thereon in a first dimension, the second cylindrical lens is configured to further converge the incident photons after passing through the first cylindrical lens in a second dimension, and the first dimension is perpendicular to the second dimension.

According to an embodiment, each focal length of the first and second cylindrical lenses is positive, and the focal length of the first cylindrical lens is shorter than the focal length of the second cylindrical lens.

Docket No. 1810-0132

### BRIEF DESCRIPTION OF FIGURES

FIG. 1 schematically shows the electric current in an APD (avalanche photodiode) as a function of the intensity of light incident on the APD when the APD is in the linear mode, and a function of the intensity of light incident on the APD when the APD is in the Geiger mode.

FIG. 2A, FIG. 2B and FIG. 2C schematically show the operation of an APD, according to an embodiment.

FIG. 3A schematically shows a cross-sectional view of an image sensor based on an array of APDs.

FIG. 3B shows a variant of the image sensor of FIG. 3A.

FIG. 3C shows a variant of the image sensor of FIG. 3A.

FIG. 3D shows a variant of the image sensor of FIG. 3A.

FIG. 4A-FIG. 4H schematically show a method of making the image sensor.

FIG. 5 schematically shows a Lidar system, according to an embodiment.

FIG. 6 shows a flowchart summarizing and generalizing the operation of the Lidar system, according to an embodiment.

FIG. 7 shows a flowchart summarizing and generalizing the operation of the Lidar system 500, according to another embodiment.

FIG. 8A schematically shows a perspective view of the optical system of the Lidar system, according to an embodiment.

FIG. 8B schematically shows a perspective view of the optical system, according to another embodiment.

FIG. 8C schematically shows the operation of the optical system, according to an embodiment.

### DETAILED DESCRIPTION

An avalanche photodiode (APD) is a photodiode that uses the avalanche effect to generate an electric current upon exposure to light. The avalanche effect is a process where free charge carriers in a material are subjected to strong acceleration by an electric field and subsequently collide with other atoms of the material, thereby ionizing them (impact ionization) and releasing additional charge carriers which accelerate and collide with further atoms, releasing more charge carriers—a chain reaction.

Impact ionization is a process in a material by which one energetic charge carrier can lose energy by the creation of other charge carriers. For example, in semiconductors, an electron (or hole) with enough kinetic energy can knock a bound electron out of its bound state (in the valence band) and promote it to a state in the conduction band, creating an electron-hole pair.

An APD may work in the Geiger mode or the linear mode. When the APD works in the Geiger mode, it may be called a single-photon avalanche diode (SPAD) (also known as a Geiger-mode APD or G-APD). A SPAD is an APD working under a reverse bias above the breakdown voltage. Here the word “above” means that absolute value of the reverse bias is greater than the absolute value of the breakdown voltage.

A SPAD may be used to detect low intensity light (e.g., down to a single photon) and to signal the arrival times of the photons with a jitter of a few tens of picoseconds. A SPAD may be in a form of a p-n junction under a reverse bias (i.e., the p-type region of the p-n junction is biased at a lower electric potential than the n-type region) above the breakdown voltage of the p-n junction. The breakdown voltage of a p-n junction is a reverse bias, above which exponential increase in the electric current in the p-n junction occurs.

An APD may work in linear mode. An APD working at a reverse bias below the breakdown voltage is operating in the linear mode because the electric current in the APD is proportional to the intensity of the light incident on the APD.

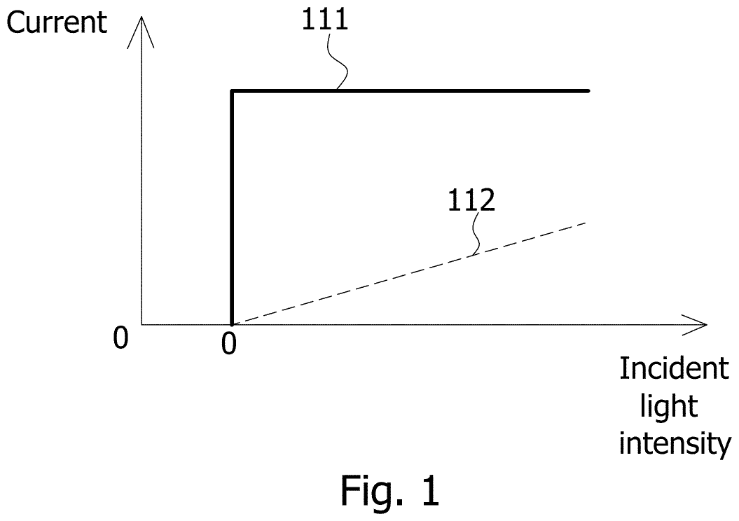

FIG. 1 schematically shows the electric current in an APD as a function 112 of the intensity of light incident on the APD when the APD is in the linear mode, and a function 111 of the intensity of light incident on the APD when the APD is in the Geiger mode (i.e., when the APD is a SPAD). In the Geiger mode, the current shows a very sharp increase with the intensity of the light and then saturation. In the linear mode, the current is essentially proportional to the intensity of the incident light.

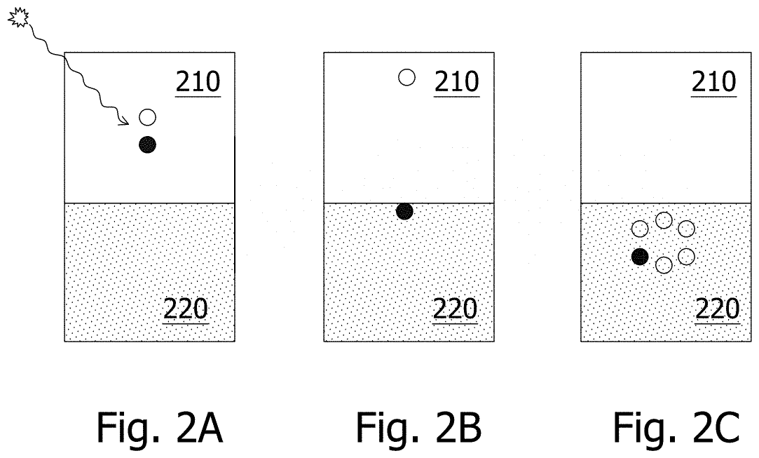

FIG. 2A, FIG. 2B and FIG. 2C schematically show the operation of an APD, according to an embodiment. FIG. 2A shows that when a photon (e.g., an X-ray photon) is absorbed by an absorption region 210 of the APD, multiple (100 to 10000 for an X-ray photon) electron-hole pairs may be generated. However, for simplicity, only one electron-hole pair is shown. The absorption region 210 has a sufficient thickness and thus a sufficient absorptance (e.g., >80% or >90%) for the incident photon. For soft X-ray photons, the absorption region 210 may be a silicon layer with a thickness of 10 microns or above. The electric field in the absorption region 210 is not high enough to cause avalanche effect in the absorption region 210.

FIG. 2B shows that the electrons and holes drift in opposite directions in the absorption region 210. FIG. 2C shows that avalanche effect occurs in an amplification region 220 when the electrons (or the holes) enter that amplification region 220, thereby generating more electrons and holes. The electric field in the amplification region 220 is high enough to cause an avalanche of charge carriers entering the amplification region 220 but not too high to make the avalanche effect self-sustaining. A self-sustaining avalanche is an avalanche that persists after the external triggers disappear, such as photons incident on the APD or charge carriers drifted into the APD.

The electric field in the amplification region 220 may be a result of a doping profile in the amplification region 220. For example, the amplification region 220 may include a p-n junction or a heterojunction that has an electric field in its depletion zone. The threshold electric field for the avalanche effect (i.e., the electric field above which the avalanche effect occurs and below which the avalanche effect does not occur) is a property of the material of the amplification region 220. The amplification region 220 may be on one or two opposite sides of the absorption region 210.

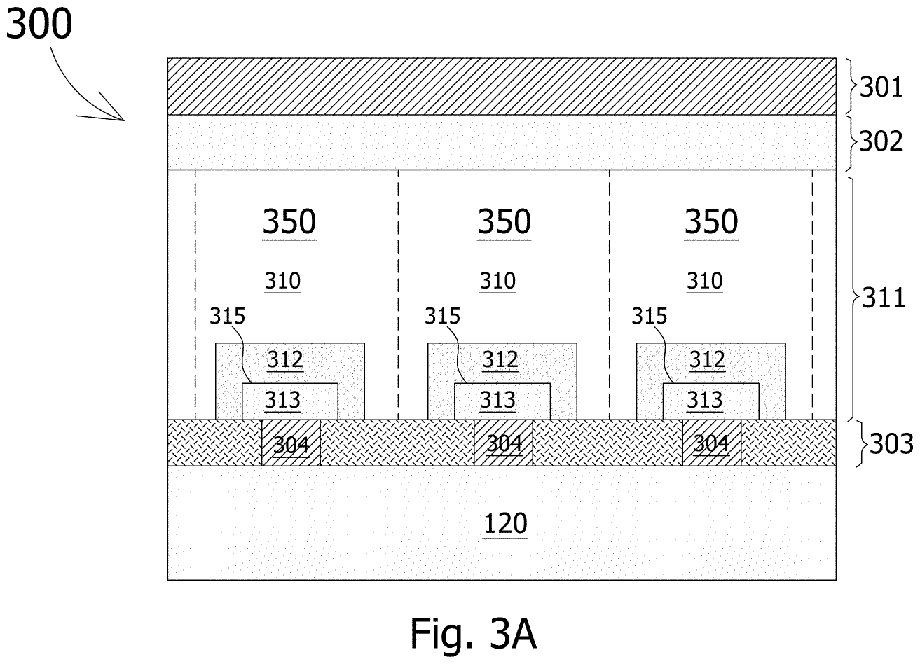

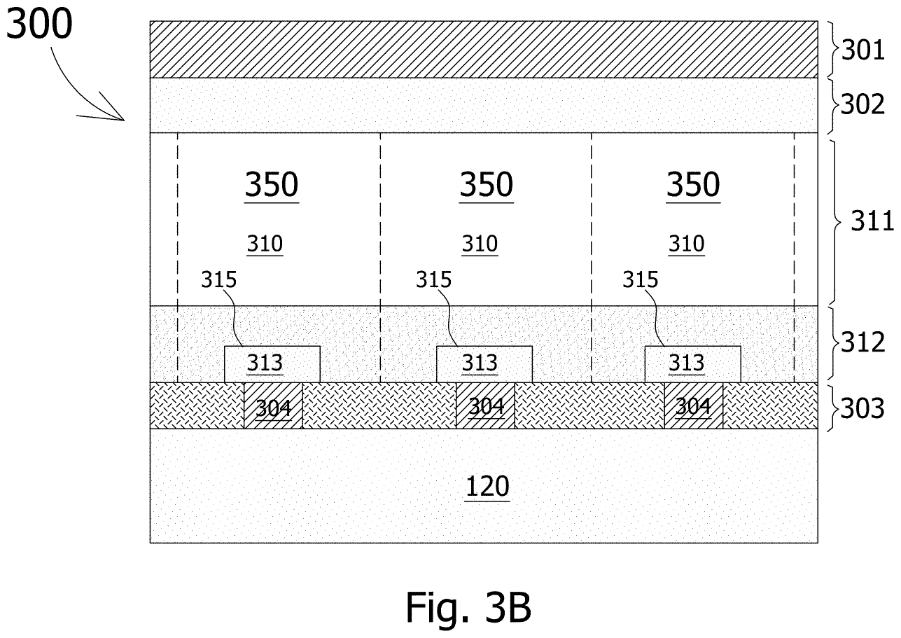

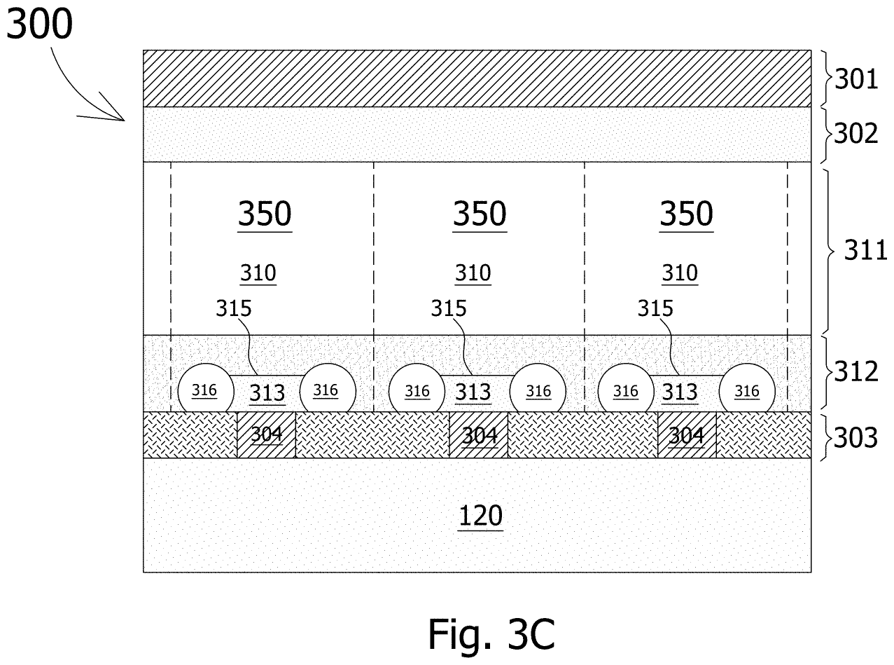

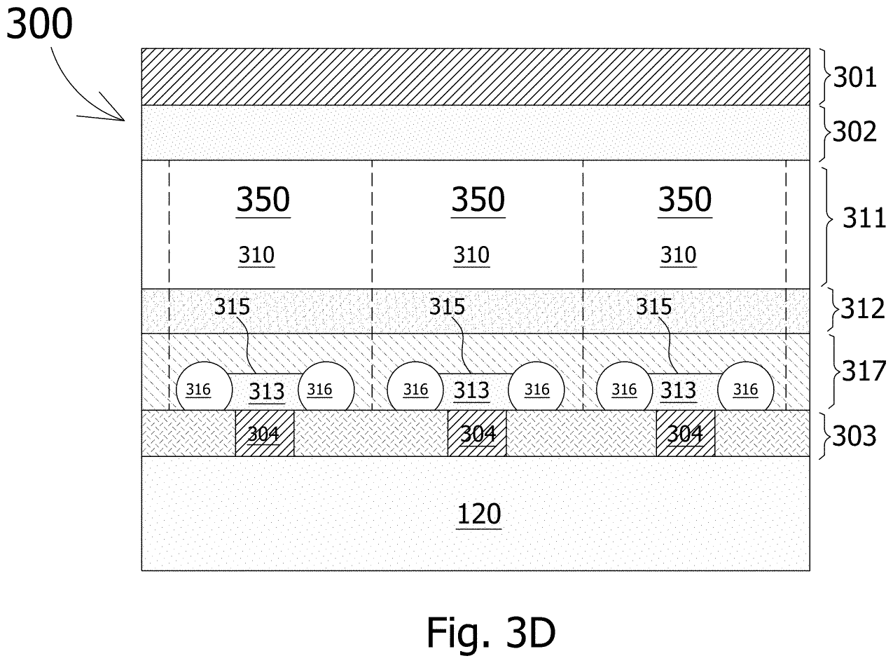

FIG. 3A schematically shows a cross-sectional view of an image sensor 300 based on an array of APDs 350 (also called sensing elements 350 or pixels 350). Each of the APDs 350 may have an absorption region 310 and an amplification region 312+313 as the example shown in FIG. 2A, FIG. 2B and FIG. 2C. At least some, or all, of the APDs 350 in the image sensor 300 may have their absorption regions 310 joined together. Namely, the image sensor 300 may have joined absorption regions 310 in a form of an absorption layer 311 that is shared among at least some or all of the APDs 350.

The amplification regions 312+313 of the APDs 350 are discrete regions. Namely the amplification regions 312+313 of the APDs 350 are not joined together. In an embodiment, the absorption layer 311 may be in form of a semiconductor wafer such as a silicon wafer. The absorption regions 310 may be an intrinsic semiconductor or very lightly doped semiconductor (e.g., <10¹² dopants/cm³, <10¹¹ dopants/cm³, <10⁹ dopants/cm³, <10⁹ dopants/cm³), with a sufficient thickness and thus a sufficient absorptance (e.g., >80% or >90%) for incident photons of interest (e.g., X-ray photons).

The amplification regions 312+313 may have a junction 315 formed by at least two layers 312 and 313. The junction 315 may be a heterojunction of a p-n junction. In an embodiment, the layer 312 is a p-type semiconductor (e.g., silicon) and the layer 313 is a heavily doped n-type layer (e.g., silicon). The phrase “heavily doped” is not a term of degree. A heavily doped semiconductor has its electrical conductivity comparable to metals and exhibits essentially linear positive thermal coefficient. In a heavily doped semiconductor, the dopant energy levels are merged into an energy band. A heavily doped semiconductor is also called degenerate semiconductor.

The layer 312 may have a doping level of 10¹³ to 10¹⁷ dopants/cm³. The layer 313 may have a doping level of 10¹⁸ dopants/cm³ or above. The layers 312 and 313 may be formed by epitaxy growth, dopant implantation or dopant diffusion. The band structures and doping levels of the layers 312 and 313 can be selected such that the depletion zone electric field of the junction 315 is greater than the threshold electric field for the avalanche effect for electrons (or for holes) in the materials of the layers 312 and 313, but is not too high to cause self-sustaining avalanche. Namely, the depletion zone electric field of the junction 315 should cause avalanche when there are incident photons in the absorption region 310 but the avalanche should cease without further incident photons in the absorption region 310.

The image sensor 300 may further include electrodes 304 respectively in electrical contact with the layer 313 of the APDs 350. The electrodes 304 are configured to collect electric currents flowing through the APDs 350. The image sensor 300 may further include a passivation material 303 configured to passivate surfaces of the absorption regions 310 and the layer 313 of the APDs 350 to reduce recombination at these surfaces.

The image sensor 300 may further include an electronics layer 120 which may include an electronic system electrically connected to the electrodes 304. The electronic system is suitable for processing or interpreting electrical signals (i.e., the charge carriers) generated in the APDs 350 by the radiation incident on the absorption regions 310. The electronic system may include an analog circuitry such as a filter network, amplifiers, integrators, and comparators, or a digital circuitry such as a microprocessor, and memory. The electronic system may include one or more analog-to-digital converters.

The image sensor 300 may further include a heavily doped layer 302 disposed on the absorption regions 310 opposite to the amplification regions 312+313, and a common electrode 301 on the heavily doped layer 302. The common electrode 301 of at least some or all of the APDs 350 may be joined together. The heavily doped layer 302 of at least some or all of the APDs 350 may be joined together.

When a photon incidents on the image sensor 300, it may be absorbed by the absorption region 310 of one of the APDs 350, and charge carriers may be generated in the absorption region 310 as a result. One type (electrons or holes) of the charge carriers drift toward the amplification region 312+313 of that one APD. When the charge carriers enter the amplification region 312+313, the avalanche effect occurs and causes amplification of the charge carriers. The amplified charge carriers may be collected by the electronics layer 120 through the electrode 304 of that one APD, as an electric current.

When that one APD is in the linear mode, the electric current is proportional to the number of incident photons in the absorption region 310 per unit time (i.e., proportional to the light intensity at that one APD). The electric currents at the APDs may be compiled to represent a spatial intensity distribution of light, i.e., a 2D image. The amplified charge carriers may alternatively be collected through the electrode 304 of that one APD, and the number of photons may be determined from the charge carriers (e.g., by using the temporal characteristics of the electric current).

The junctions 315 of the APDs 350 should be discrete, i.e., the junction 315 of one of the APDs should not be joined with the junction 315 of another one of the APDs. Charge carriers amplified at one of the junctions 315 of the APDs 350 should not be shared with another of the junctions 315.

The junction 315 of one of the APDs may be separated from the junctions 315 of the neighboring APDs (a) by the material of the absorption region wrapping around the junction, (b) by the material of the layer 312 or 313 wrapping around the junction, (c) by an insulator material wrapping around the junction, or (d) by a guard ring of a doped semiconductor.

As shown in FIG. 3A, the layer 312 of each of the APDs 350 may be discrete, i.e., not joined with the layer 312 of another one of the APDs; the layer 313 of each of the APDs 350 may be discrete, i.e., not joined with the layer 313 of another one of the APDs. FIG. 3B shows a variant of the image sensor 300, where the layers 312 of some or all of the APDs are joined together.

FIG. 3C shows a variant of the image sensor 300, where the junction 315 is surrounded by a guard ring 316. The guard ring 316 may be an insulator material or a doped semiconductor. For example, when the layer 313 is heavily doped n-type semiconductor, the guard ring 316 may be n-type semiconductor of the same material as the layer 313 but not heavily doped. The guard ring 316 may be present in the image sensor 300 shown in FIG. 3A or FIG. 3B.

FIG. 3D shows a variant of the image sensor 300, where the junction 315 has an intrinsic semiconductor layer 317 sandwiched between the layer 312 and 313. The intrinsic semiconductor layer 317 in each of the APDs 350 may be discrete, i.e., not joined with other intrinsic semiconductor layer 317 of another APD. The intrinsic semiconductor layers 317 of some or all of the APDs 350 may be joined together.

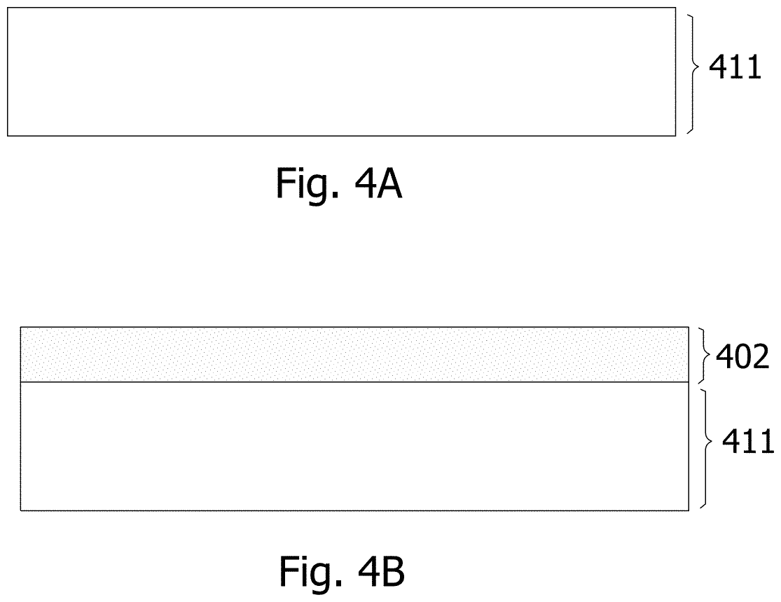

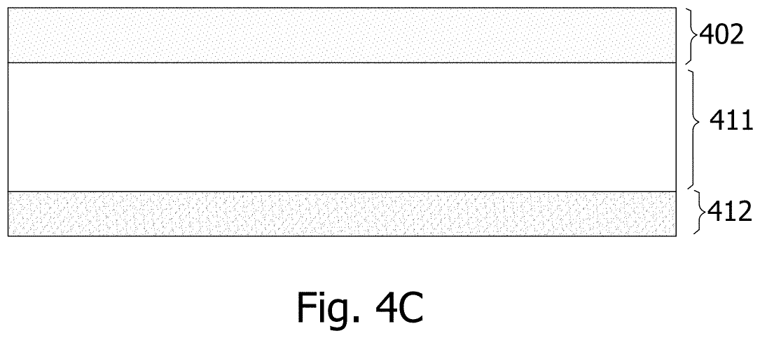

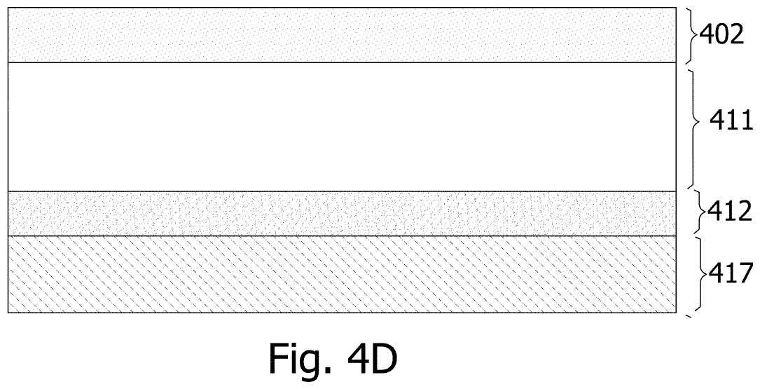

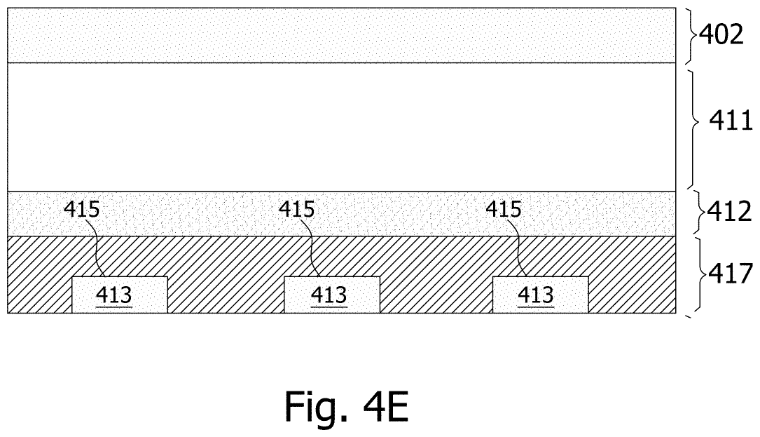

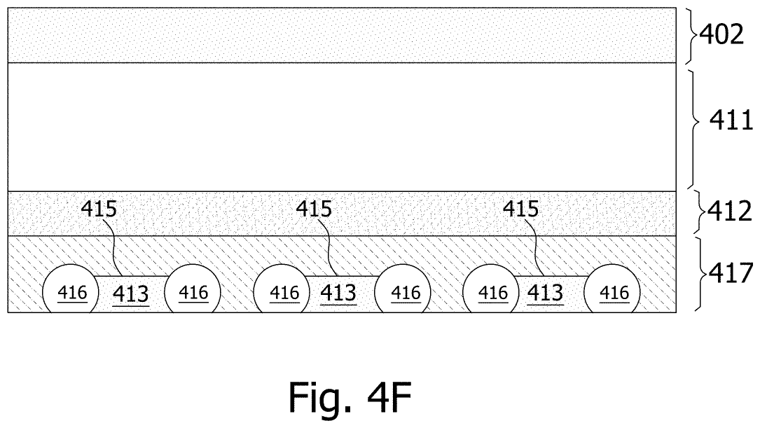

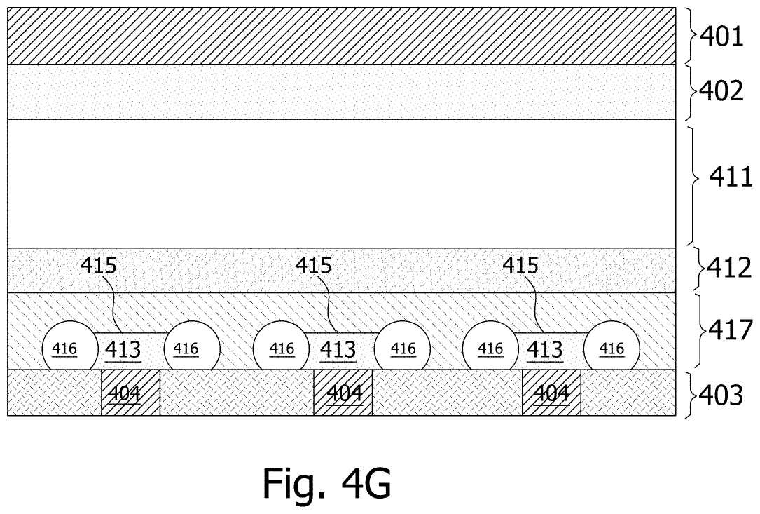

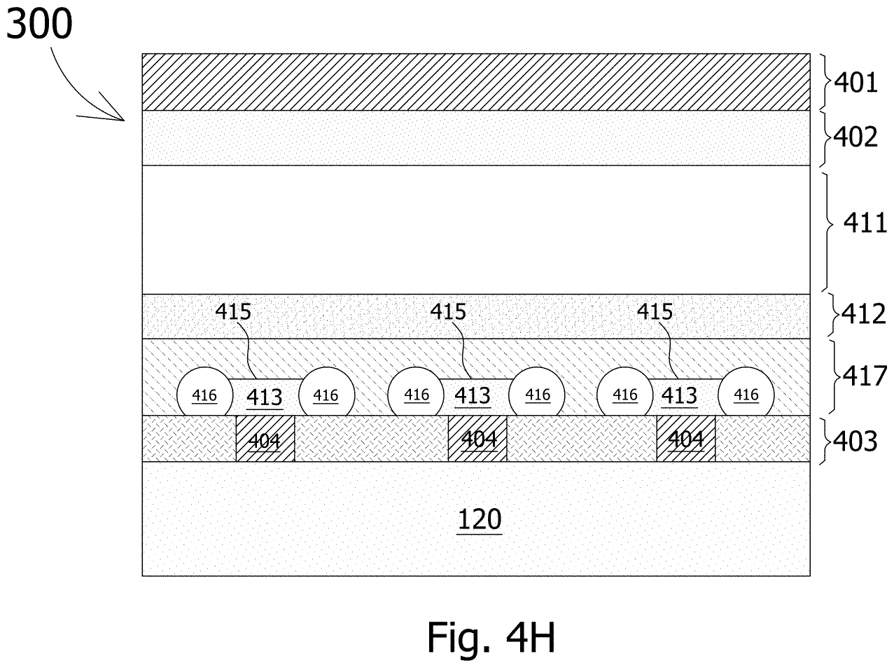

FIG. 4A-FIG. 4H schematically show a method of making the image sensor 300. The method may start with obtaining a semiconductor substrate 411 (FIG. 4A). The semiconductor substrate 411 may be a silicon substrate. The semiconductor substrate 411 is an intrinsic semiconductor or very lightly doped semiconductor (e.g., <10¹² dopants/cm³, <10¹¹ dopants/cm³, <10¹⁰ dopants/cm³, <10⁹ dopants/cm³), with a sufficient thickness and thus a sufficient absorptance (e.g., >80% or >90%) for incident photons of interest (e.g., X-ray photons).

A heavily doped layer 402 (FIG. 4B) is formed on one side of the semiconductor substrate 411. The heavily doped layer 402 (e.g., heavily doped p-type layer) may be formed for diffusing or implanting a suitable dopant into the substrate 411.

A doped layer 412 (FIG. 4C) is formed on the side of the semiconductor substrate 411 opposite to the heavily doped layer 402. The layer 412 may have a doping level of 10¹³ to 10¹′ dopants/cm³. The layer 412 may be the same (i.e., the layer 412 is p-type if the layer 402 is p-type and the layer 412 is n-type if the layer 402 is n-type) doping type as the heavily doped layer 402. The layer 412 may be formed by diffusing or implanting a suitable dopant into the substrate 411 or by epitaxy growth. The layer 412 may be a continuous layer or may have discrete areas.

An optional layer 417 (FIG. 4D) may be formed on the layer 412. The layer 417 may be completely separated from the material of the substrate 411 by the layer 412. Namely, if the layer 412 has discrete regions, the layer 417 has discrete regions. The layer 417 is an intrinsic semiconductor. The layer 417 may be formed by epitaxy growth.

A layer 413 (FIG. 4E) is formed on the layer 417 if it is present, or on the layer 412 if the layer 417 is not present. The layer 413 may be completely separated from the material of the substrate 411 by the layer 412 or the layer 417. The layer 413 may have discrete areas. The layer 413 is a heavily doped semiconductor having the opposite (i.e., the layer 413 is n-type if the layer 412 is p-type; the layer 413 is p-type if the layer 412 is n-type) type of dopant as the layer 412. The layer 413 may have a doping level of 10¹⁸ dopants/cm³ or above.

The layer 413 may be formed by diffusing or implanting a suitable dopant into the substrate 411 or by epitaxy growth. The layer 413, the layer 412, and the layer 417 if present, form discrete junctions 415 (e.g., p-n junctions, p-i-n junctions, hetero junctions).

Optional guard rings 416 (FIG. 4F) may be formed around the junctions 415. The guard ring 416 may be a semiconductor of the same doping type as the layer 413 but not heavily doped.

A passivation material 403 (FIG. 4G) may be applied to passivate surfaces of the substrate 411, the layers 412 and 413. Electrodes 404 may be formed and electrically connected to the junctions 415 through the layer 413. A common electrode 401 may be formed on the heavily doped layer 402 for electrical connection thereto.

An electronics layer 120 (FIG. 4H) on a separate substrate may be bonded to the structure of FIG. 4G such that the electronic system in the electronics layer 120 becomes electrically connected to the electrodes 404, resulting in the image sensor 300.

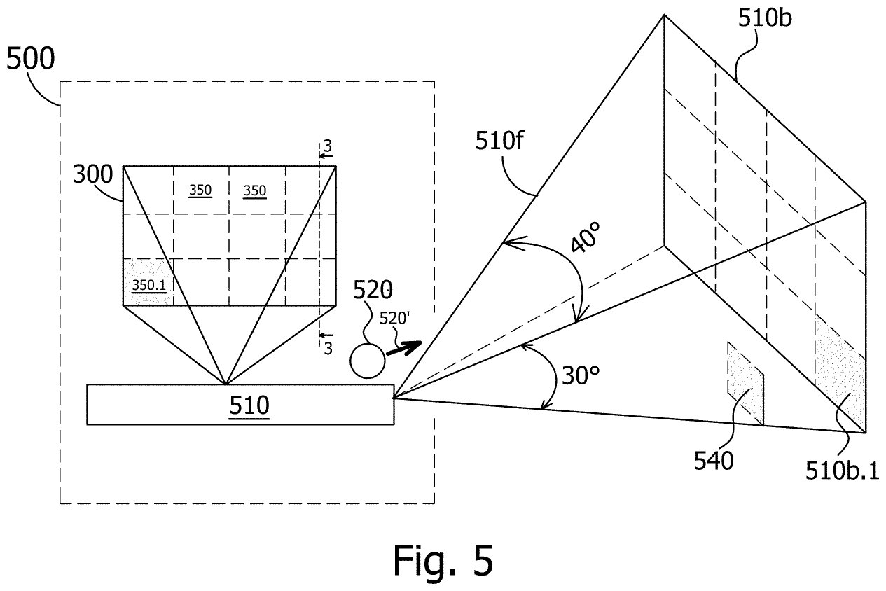

A top view of the image sensor 300 of FIG. 3A-FIG. 3D is shown in FIG. 5, in an embodiment. Specifically, with reference to FIG. 5, the image sensor 300 may include 12 APDs 350 arranged in a rectangular array of 3 rows and 4 columns. FIG. 3A-FIG. 3D are 4 cross-sectional views of the image sensor 300 of FIG. 5 along a line 3-3 according to different embodiments. In general, the image sensor 300 may include any number of APDs 350 arranged in any way.

FIG. 5 schematically shows a Lidar (Light Detection and Ranging) system 500, in an embodiment. The Lidar system 500 may include the image sensor 300, an optical system 510, and a radiation source 520 electrically connected to the image sensor 300. The Lidar system 500 may be used for capturing a range image (also called a three-dimensional contour) of the objects such as human faces, people, chairs, trees, etc.

In an embodiment, the operation of the Lidar system 500 in capturing range images of objects may be as follows. Firstly, the Lidar system 500 may be arranged or configured (or both) so that the objects whose range image is to be captured (referred to as targeted objects) are in a field of view (FOV) 510f of the Lidar system 500. The targeted objects may also be arranged (or moved) if possible so as to be in the FOV 510f of the Lidar system 500. For example, if the Lidar system 500 is used for capturing a range image of a person's face, then the Lidar system 500 may be arranged or configured (or both) and/or the person may move so that the person's face is in the FOV 510f and facing the Lidar system 500. All photons propagating in the FOV 510f and then into the optical system 510 are guided by the optical system 510 to the 12 APDs 350 of the image sensor 300.

In an embodiment, the FOV 510f may be 40° horizontal and 30° vertical. In other words, the FOV 510f has a shape of a right pyramid with its apex being the Lidar system 500 (or the optical system 510, to be more specific) and its base 510b being a rectangle at a very large distance from the apex (or at infinity for simplicity). Because the optical system 510 is considered the apex of the FOV 510f, the apex can be referred to as the apex 510.

In an embodiment, the FOV 510f may be deemed to include 12 sub-fields of view (sub-FOV) corresponding to the 12 APDs 350 of the image sensor 300 such that all photons propagating in a sub-FOV and then into the optical system 510 is guided by the optical system 510 to the corresponding APD 350. Specifically, the base 510b of the FOV 510f may be deemed to comprise 12 base rectangles arranged in an array of 3 rows and 4 columns. Each base rectangle and the apex 510 form a subpyramid that represents a sub-FOV of the 12 sub-FOVs. For example, the base rectangle 510b.1 and the apex 510 form a subpyramid that represents the sub-FOV corresponding to the APD 350.1 (hereafter, this subpyramid, this sub-FOV, and this base rectangle use the same reference numeral 510b.1 for simplicity). As a result, all photons propagating in this sub-FOV 510b.1 and then into the optical system 510 are guided by the optical system 510 to the corresponding APD 350.1 of the image sensor 300.

In an embodiment, while the targeted objects are in the FOV 510f of the Lidar system 500, the radiation source 520 may emit a pulse (or flash or burst) 520′ of illumination photons toward the targeted objects so as to illuminate these targeted objects.

Regarding the operation of the Lidar system 500 with respect to the APD 350.1, assume that the corresponding sub-FOV 510b.1 intersects a surface of a targeted object facing the Lidar system 500 via a surface spot 540 (also referred to as a spot of the scene). Assume further that a photon of the pulse 520′ bounces off the surface spot 540, returns to the Lidar system 500 (or the optical system 510 to be more specific), and is guided by the optical system 510 to the corresponding APD 350.1. As a result, this photon contributes to cause a spike (i.e., a sharp increase) in the number of charge carriers in the APD 350.1. The more photons of the pulse 520′ that bounce off the surface spot 540 in the sub-FOV 510b.1, return to the Lidar system 500, and enter the APD 350.1, the larger the spike, and the more easily the spike may be detected by the electronics layer 120 of the image sensor 300.

In an embodiment, the electronics layer 120 may be configured to (a) measure the time period (called the time-of-flight or TOF for short) from the time at which the pulse 520′ is emitted by the radiation source 520 to the time at which the spike in the number of charge carriers in the APD 350.1 occurs, and then (b) based on the measured TOF, determine the spot distance from the Lidar system 500 to the surface spot 540. In an embodiment, the formula used to determine this spot distance is: D=½ (c×TOF), where D is the spot distance and c is the speed of light in vacuum (around 3×10⁸ m/s). For example, if the measured TOF is 60 ns, then D=½ (3×10⁸ m/s×60 ns)=9 m.

In an alternative embodiment, the spot distance may be expressed in terms of the time it would take light to propagate from the Lidar system 500 to the surface spot 540. In this alternative embodiment, the formula used to determine this spot distance is: D=½ TOF. For example, if the measured TOF is 60 ns, then D=½ (60 ns)=30 ns.

In an embodiment, the operation of the Lidar system 500 with respect to the other 11 APDs 350 are similar to the operation of the Lidar system 500 with respect to the APD 350.1 as described above. As a result, in total, the Lidar system 500 determines 12 spot distances from the Lidar system 500 to 12 surface spots in the 12 sub-FOVs. These 12 spot distances include the one spot distance from the Lidar system 500 to the surface spot 540 in the sub-FOV 510b.1 described above. These 12 spot distances constitute a range image of the targeted objects in the FOV 510f. In other words, by determining the 12 spot distances as described above, the Lidar system 500 has captured a range image of the targeted objects in the FOV 510f. This range image of the targeted objects may be deemed to have 12 image pixels arranged in a rectangular array of 3 rows and 4 columns, wherein the 12 image pixels contain the 12 spot distances mentioned above.

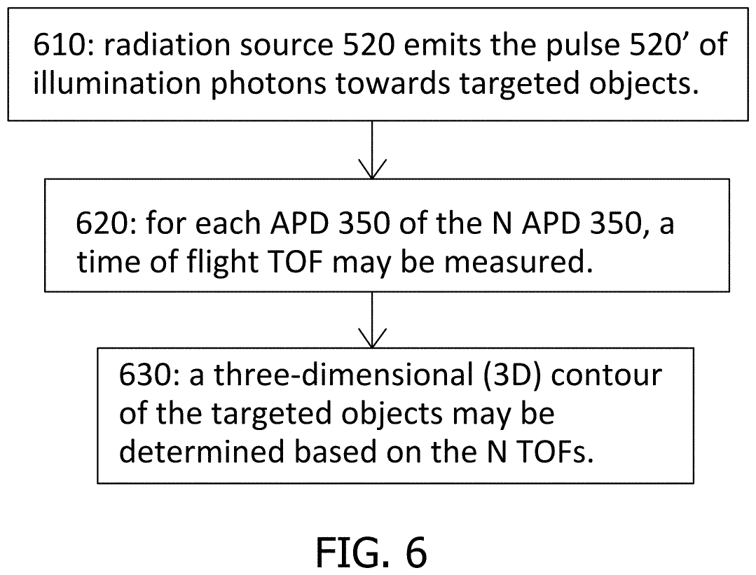

FIG. 6 shows a flowchart summarizing and generalizing the operation of the Lidar system 500 as described above. In step 610, the radiation source 520 emits the pulse 520′ of illumination photons towards the targeted objects thereby illuminating these targeted objects. Photons of the pulse 520′ that bounce off surfaces of the targeted objects and return to the Lidar system 500 are guided by the optical system 510 to the N APDs 350 of the image sensor 300 (N is a positive integer). These return photons create N spikes in the numbers of charge carriers in the N APDs 350. In step 620, for each APD 350 of the N APD 350, the time of flight TOF from the time at which the pulse 520′ is emitted by the radiation source 520 to the time at which a photon of the illumination photons returns to the APD 350 through the optical system after bouncing off a surface spot of a targeted object corresponding to the APD 350 may be measured. In step 630, for each APD 350, the spot distance from the Lidar system 500 to the surface spot corresponding to the APD 350 may be determined. In other words, collectively, in step 630, a three-dimensional (3D) contour of the targeted objects may be determined based on the N TOFs.

In an embodiment, the determined 3D contour of the targeted objects may be matched against (i.e., compared with) a previously known 3D contour. For example, the determined 3D contour may be that of the face of a person trying to pass a security checkpoint so as to enter a government building, and the determined 3D contour may be compared with a previously known 3D contour from a ban list. If there is a match, then the person may be denied entry.

In an embodiment, the pulse 520′ of photons may include infrared photons. Because infrared photons are safe for human eyes, the Lidar system 500 may be safely used in applications that usually have people near the Lidar system 500 (e.g., self driving cars, facial image capturing, etc.). Silicon is not good in absorbing incident infrared photons (i.e., Si allows infrared photons to pass essentially without absorption). As a result, the electric signals (or charge carriers) created in silicon absorption regions of a typical image sensor of the prior art are rather weak and therefore may be obscured by electrical noise within the typical image sensor. In contrast, the APDs 350 of the present disclosure, even if being made of silicon, through the avalanche effect, significantly amplify the electrical signals which incident infrared photons create in the silicon absorption regions 310. As a result, these amplified electrical signals (i.e., the spikes mentioned above) may be easily detected by the electronics layer 120. This means that the Lidar system 500 which comprises mostly silicon is functional. Because Si is a reasonably cheap semiconductor material, the Lidar system 500 which comprises mostly silicon (in an embodiment) is reasonably cheap to make.

In the embodiments described above, the image sensor 300 includes 12 APDs 350. In general, the image sensor 300 may include N APDs 350 (N being a positive integer) arranged in any way (i.e., not necessarily in a rectangular array as described above). The more APDs 350 the image sensor 300 has, the higher spatial distance resolution the captured range image has. With N>1 as described above, the Lidar system 500 is usually referred to as a Flash Lidar system.

For the case N=1, the image sensor 300 has only 1 APD 350. In this case, in an embodiment, the FOV 510f may be narrowed down such that the FOV 510f is, for example, 1° horizontal and 1° vertical. Accordingly, the pulse 520′ of illumination photons may be focused on the narrow FOV 510f and would look like a narrow beam that illuminates essentially only the targeted objects in the narrow FOV 510f. An advantage of this case (N=1) is that because the power of the pulse 520′ of illumination photons is focused on the narrow FOV 510f, the Lidar system 500 may capture a range image of targeted objects farther away from the Lidar system 500. For example, the Lidar system 500 of this case (N=1) may be mounted on a flying airplane to capture range images of the ground below in sequence while the FOV 510f scans the ground (i.e., the FOV 510f is directed at a new spot of the scene before the Lidar system 500 captures a new range image).

In the embodiments described above, the electronic system of the electronics layer 120 of the image sensor 300 includes all the electronics components needed for TOF measurements and spot distance determinations. In an alternative embodiment, the Lidar system 500 may further include a separate signal processor (or even a computer) electrically connected to the image sensor 300 and the radiation source 520 such that both the electronic system of the electronics layer 120 and the signal processor may work together to handle the TOF measurements and spot distance determinations. As a result, in this alternative embodiment, the electronics layer 120 of the image sensor 300 does not have to include all the electronics needed for the TOF measurements and spot distance calculations, and therefore may be fabricated more easily.

In an embodiment, after capturing the range image of the targeted objects as described above, the Lidar system 500 may be used for capturing more range images in a similar manner. Specifically, if the Lidar system 500 is mounted on a self driving car to monitor surrounding objects, then before each range image is captured, the Lidar system 500 may be arranged or configured (or both) so that the FOV 510f is directed at a new scene. For example, the Lidar system 500 (or the FOV 510f, to be more specific) may be rotated 40° around a vertical axis going through the Lidar system 500 before each new range image is captured. As a result, 9 range images are captured for each revolution of 360° scene surrounding the self driving car.

Alternatively, if the Lidar system 500 is used to monitor a room for intruders, then in an embodiment, the FOV 510f of the Lidar system 500 may remain stationary with respect to the room while the Lidar system 500 captures range images of the room objects in the FOV 510f in sequence (i.e., captures one range image after another).

Next, in an embodiment, the Lidar system 500 may be configured to compare a first range image captured by the Lidar system 500 at a first time point and a second range image captured by the Lidar system 500 at a second time point, wherein the second time point is Td seconds after the first time point. For example, Td may be chosen to be 10 seconds to make it unlikely that the intruder's image in the first range image overlaps the intruder's image in the second range image when the first and second range images are superimposed on each other.

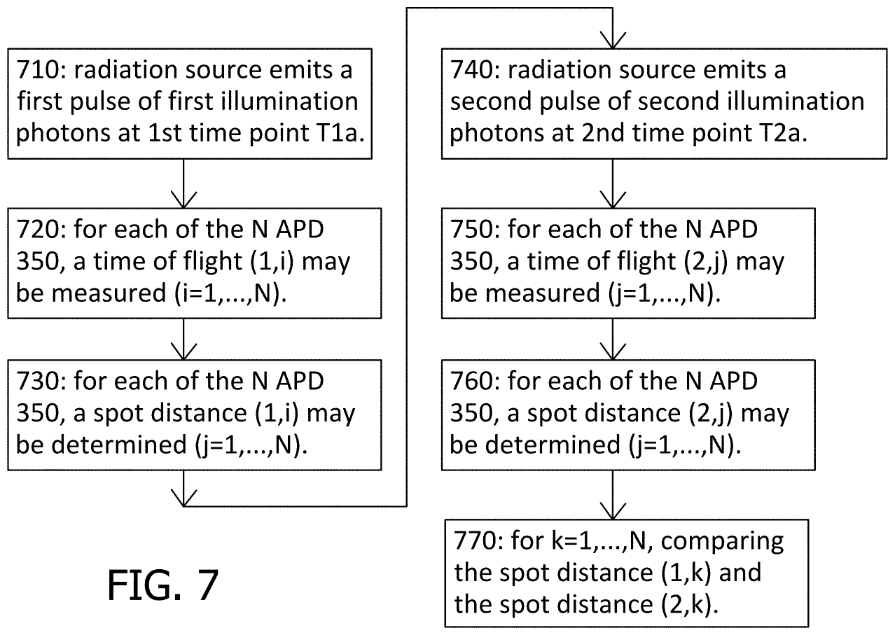

FIG. 7 shows a flowchart summarizing and generalizing the operation of the Lidar system 500 in comparing two range images. In step 710, the radiation source 520 emits a first pulse of first illumination photons at a first time point T1a. In step 720, for each of the N APD 350, a time of flight (1,i) may be measured (i.e., i=1, . . . ,N). In step 730, for each of the N APD 350, a spot distance (1,i) may be determined (i.e., i=1, . . . ,N). In step 740, the radiation source 520 emits a second pulse of second illumination photons at a second time point T2a which is after the first time point T1a. In step 750, for each of the N APD 350, a time of flight (2,j) may be measured (i.e., j=1, . . . ,N). In step 760, for each of the N APD 350, a spot distance (2,j) may be determined (i.e., j=1, . . . ,N). In step 770, for each of the N APD 350, the spot distance (1,k) and the spot distance (2,k) may be compared (i.e., k=1, . . . ,N). In other words, the first and second range images captured at time points T1a and T2a, respectively, are compared.

In an embodiment, the comparison of the first and second range images may include determining the difference between the first and second range images as follows. A range change image of size 3×4 representing the difference between the first and second range images may be obtained by subtracting the second range image from the first range image. Specifically, assume the first range image includes 12 spot distances D1(i), i=1, . . . ,12, and the second range image includes 12 spot distances D2(i), i=1, . . . ,12, then the range change image includes 12 range changes RC(i), i=1, . . . ,12 wherein for i=1, . . . ,12, the range change RC(i)=D1(i)−D2(i). In an embodiment, an alarm may be triggered if the absolute value (i.e., modulus) of at least one of the 12 range changes RC(i), i=1, . . . ,12 exceeds a pre-specified positive threshold.

Next, in an embodiment, based on the range change image obtained as described above, the Lidar system 500 may be configured to identify the suspicious pixel positions of the 3×4 array of 12 pixel positions that experience changes when the first and second range images are compared. Specifically, based on the range change image, the Lidar system 500 may be configured to obtain a Boolean image of size 3×4 including 12 Boolean image pixels (i), i=1, . . . ,12 as follows. For i=1, . . . ,12, if the absolute value of RC(i) exceeds a positive threshold value pre-specified by the user of the Lidar system 500, then the Boolean image pixel (i) of the Boolean image is set to TRUE. Otherwise, the Boolean image pixel (i) of the Boolean image is set to FALSE. The TRUE Boolean image pixels identify the suspicious pixel positions.

Next, in an embodiment, the Lidar system 500 may be configured to apply an algorithm on the suspicious pixel positions identified as described above to determine whether these suspicious pixel positions collectively have a size and shape of a human body in the 3×4 array of the 12 pixel positions. If the answer is yes, then the Lidar system 500 may be configured to trigger a security alarm system to indicate that an intruder is likely in the room.

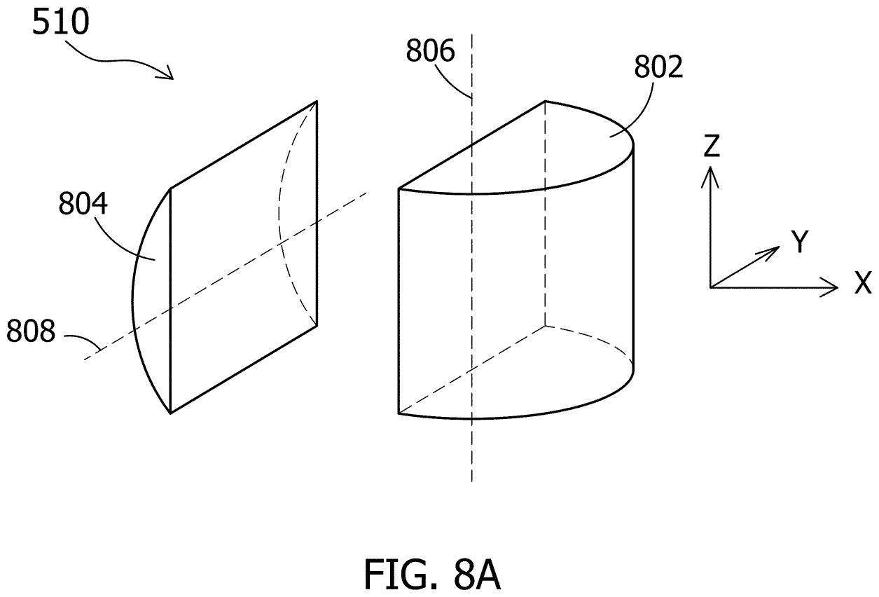

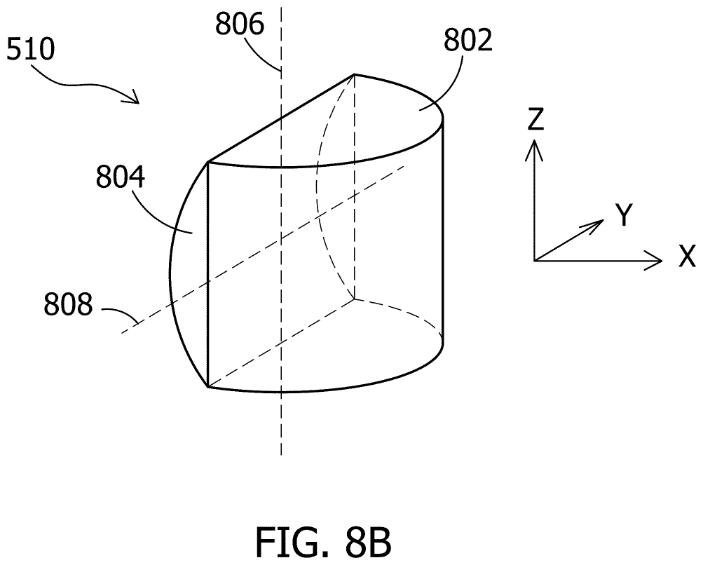

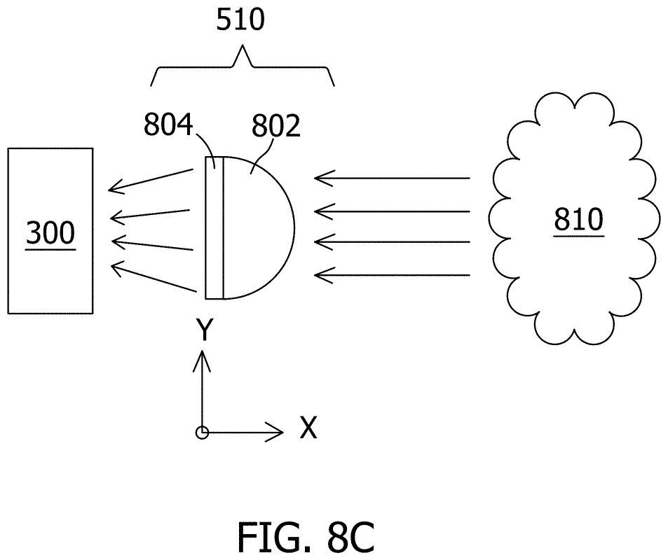

In an embodiment, with reference to FIG. 5, the optical system 510 may be configured to converge return photons that have bounced off spot surfaces of the targeted objects to generate converged return photons towards the sensing elements 350 (e.g., the APDs 350) of the image sensor 300. FIG. 8A schematically shows a perspective view of the optical system 510, according to one embodiment. The optical system 510 may comprise a first cylindrical lens 802 and a second cylindrical lens 804. The first and second cylindrical lenses 802 and 804 may be separated from each other.

FIG. 8B schematically shows a perspective view of the optical system 510, according to another embodiment. In example of FIG. 8B, the first and second cylindrical lenses 802 and 804 may be attached to each other. Specifically, the rectangular face of the first cylindrical lens 802 attaches to the rectangular face of the second cylindrical lens 804.

In an embodiment, the first cylindrical lens 802 and the second cylindrical lens 804 may be arranged orthogonal to each other, that is, the axial axis of the first cylindrical lens 802 (e.g., dashed line 806 in Z direction in FIG. 8A and FIG. 8B) is perpendicular to the axial axis of the second cylindrical lens 804 (e.g., dashed line 808 in Y direction in FIG. 8A and FIG. 8B).

In an embodiment, each focal length of the first and second cylindrical lenses 802 and 804 may be positive. In example of FIG. 8A and FIG. 8B, both the first and second cylindrical lenses 802 and 804 may have a plano-convex configuration. In an embodiment, the focal length of the first cylindrical lens 802 may be shorter than the focal length of the second cylindrical lens 804.

FIG. 8C schematically shows the operation of the optical system 510 comprising the first cylindrical lens 802 and the second cylindrical lens 804 (top view), according to an embodiment. The first cylindrical lens 802 may be positioned between the targeted objects 810 and the second cylindrical lens 804. The second cylindrical lens 804 may be positioned between the first cylindrical lens 802 and the sensing elements 350 of the image sensor 300.

In example of FIG. 8C, the axial axis of the first cylindrical lens 802 is in the Z direction (e.g., pointing out of the X-Y plane) and the curved face of the first cylindrical lens 802 is facing toward the targeted objects 810. The axial axis of the second cylindrical lens 804 is in the Y direction, and the curved face of the second cylindrical lens 804 is facing toward the sensing elements 350 of the image sensor 300.

When the targeted objects 810 are illuminated by a pulse of illumination photons generated by the radiation source 520 (FIG. 5), the resulting return photons may hit different locations on the curved face of the first cylindrical lens 802. The first cylindrical lens 802 may converge the return photons incident thereon in the Y dimension (also called the first dimension). The second cylindrical lens 804 may further converge the return photons after passing through the first cylindrical lens 802 in the Z dimension (also called the second dimension which is perpendicular to the first dimension) so that the converged return photons propagate towards the image sensor 300 and are received by the sensing elements 350 (FIG. 5) of the image sensor 300.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

1. A method of operating an apparatus which comprises (a) an image sensor comprising an array of avalanche photodiodes (APDs)(i), i=1, . . . ,N, N being a positive integer, for i=1, . . . ,N, the APD (i) comprising an absorption region (i) and an amplification region (i), wherein the absorption region (i) is configured to generate charge carriers from a photon absorbed by the absorption region (i), wherein the amplification region (i) comprises a junction (i) with a junction electric field (i) in the junction (i), wherein the junction electric field (i) is at a value sufficient to cause an avalanche of charge carriers entering the amplification region (i), but not sufficient to make the avalanche self-sustaining, and wherein the junctions (i), i=1, . . . ,N are discrete, (b) a radiation source, and (c) an optical system, the method comprising:
using the radiation source to emit a pulse of illumination photons at a time point Ta;
for i=1, . . . ,N, measuring a time of flight (i) from Ta to a time point Tb(i) at which a photon of the illumination photons returns to the APD (i) through the optical system after bouncing off a surface spot (i) of a targeted object corresponding to the APD (i); and
determining a three-dimensional (3D) contour of the targeted objects based on the times of flights (i), i=1, . . . ,N.

2. The method of claim 1, wherein N is greater than 1.

3. The method of claim 1,
wherein the illumination photons comprise infrared photons, and
wherein, for i=1, . . . ,N, the APD (i) comprises silicon.

4. (canceled)

5. The method of claim 1, wherein for i=1, . . . ,N, an absorption region electric field (i) in the absorption region (i) is not high enough to cause avalanche effect in the absorption region (i).

6. (canceled)

7. The method of claim 1,
wherein N>1, and
wherein at least some absorption regions of the absorption regions (i), i=1, . . . ,N are joined together.

8. The method of claim 1, wherein for i=1, . . . ,N, the APD (i) further comprises an amplification region (i′) such that the amplification region (i) and the amplification region (i′) are on opposite sides of the absorption region (i).

9. The method of claim 1, wherein the amplification regions (i), i=1, . . . ,N are discrete.

10. (canceled)

11. The method of claim 1,
wherein for i=1, . . . ,N, the junction (i) comprises a first layer (i) and a second layer (i), and
wherein for i=1, . . . ,N, the first layer (i) is a doped semiconductor and the second layer (i) is a heavily doped semiconductor.

12. The method of claim 11,
wherein for i=1, . . . ,N, the junction (i) further comprises a third layer (i) sandwiched between the first layer (i) and the second layer (i), and
wherein for i=1, . . . ,N, the third layer (i) comprises an intrinsic semiconductor.

13. The method of claim 12,
wherein N>1, and
wherein at least some third layers of the third layers (i), i=1, . . . ,N, are joined together.

14. (canceled)

15. The method of claim 11,
wherein N>1, and
wherein at least some first layers of the first layers (i), i=1, . . . ,N are joined together.

16. The method of claim 11, wherein the image sensor further comprises electrodes (i), i=1, . . . ,N in electrical contact with the second layers (i), i=1, . . . ,N, respectively.

17. The method of claim 1, wherein the image sensor further comprises a passivation material configured to passivate a surface of the absorption regions (i), i=1, . . . ,N.

18. (canceled)

19. The method of claim 1, wherein for i=1, . . . ,N, the junction (i) is separated from a junction of a neighbor junction by (a) a material of the absorption region (i), (b) a material of the first layer (i) or of the second layer (i), (c) an insulator material, or (d) a guard ring (i) of a doped semiconductor.

20. The method of claim 19,
wherein for i=1, . . . ,N, the guard ring (i) is a doped semiconductor of a same doping type as the second layer (i), and
wherein for i=1, . . . ,N, the guard ring (i) is not heavily doped.

21. The method of claim 1, further comprising matching the determined 3D contour against a previously known 3D contour.

22. The method of claim 1, wherein the optical system is configured to converge photons incident on the optical system.

23. The method of claim 22,
wherein the optical system comprises a first cylindrical lens and a second cylindrical lens, and
wherein the first cylindrical lens is positioned between the targeted objects and the second cylindrical lens.

24. The method of claim 23,
wherein the first cylindrical lens is configured to converge photons incident thereon in a first dimension,
wherein the second cylindrical lens is configured to further converge the incident photons after passing through the first cylindrical lens in a second dimension, and
wherein the first dimension is perpendicular to the second dimension.

25. The method of claim 23,
wherein each focal length of the first and second cylindrical lenses is positive, and
wherein the focal length of the first cylindrical lens is shorter than the focal length of the second cylindrical lens.
